(19) United States
(12) Patent Application Publication
(10) Pub. No.: US 2021/0104339 A1
(43) Pub. Date: Apr. 8, 2021

(54) CONDUCTIVE COMPOSITION AND METHOD FOR FABRICATING MICRO LIGHT-EMITTING DIODE DISPLAY

(71) Applicant: INDUSTRIAL TECHNOLOGY RESEARCH INSTITUTE, Hsinchu (TW)

(72) Inventors: Shou-Yi HO, New Taipei City (TW); Yen-Chun LIU, Taipei City (TW); Kuo-Chan CHIOU, Tainan City (TW); Hsien-Kuang LIN, Hsinchu City (TW)

(73) Assignee: INDUSTRIAL TECHNOLOGY RESEARCH INSTITUTE, Hsinchu (TW)

(21) Appl. No.: 16/729,940

(22) Filed: Dec. 30, 2019

(30) Foreign Application Priority Data
Oct. 2, 2019 (TW) 108135667

(51) Int. Cl. H01B 1/22; H01L 25/075; H01L 33/00; H01L 33/62; C08K 3/08; C08G 59/24

(52) U.S. Cl. CPC H01B 1/22; H01L 25/0753; H01L 33/0095; H01L 33/62; C08K 3/08; C08K 2201/001; H01L 2933/0066; C08K 2003/0806; C08K 2003/085; C08K 2003/0837; C08K 2201/005; C08G 59/245

(57) ABSTRACT

A conductive composition and a method for fabricating a micro light-emitting diode (LED) display are provided. The conductive composition includes 5-90 parts by weight of monomer, 10-95 parts by weight of epoxy resin, and 50-150 parts by weight of conductive powder. The total weight of the monomer and the epoxy resin is 100 parts by weight. The monomer has n reactive functional groups, wherein n is 1, 2, 3 or 4. The monomer has a molecular weight equal to or less than 350. The epoxy resin has an epoxy equivalent weight (EEW) from 160 g/Eq to 3500 g/Eq. Furthermore, there is a specific relationship among the weight of monomer, the number of reactive functional groups, the molecular weight of monomer, the weight of epoxy resin, and the epoxy equivalent weight of epoxy resin.

### CROSS REFERENCE TO RELATED APPLICATIONS

The application is based on, and claims priority from, Taiwan Application Serial Number 108135667, filed on Oct. 2, 2019, the disclosure of which is hereby incorporated by reference herein in its entirety.

### BACKGROUND

### Field of the Disclosure

The present disclosure relates to a conductive composition and a method for fabricating a micro light-emitting diode display.

### Description of the Related Art

With the advancements being made in the field of optoelectronics technology, the size of optoelectronic components has gradually evolved toward miniaturization. In recent years, due to breakthroughs in the size of light-emitting diodes (LEDs), micro light-emitting diode (micro LED) displays, in which arrays of light-emitting diodes are arranged in an array, have increasingly interested people in the field. A micro LED display is an active micro semiconductor device display, and it is more energy-efficient than organic light-emitting diode (OLED) displays. Furthermore, a micro LED display has better contrast performance than an OLED display, and it is visible in sunlight. In addition, since micro LED displays use inorganic material, they have better reliability and a longer lifetime than OLED displays.

The material for bonding the chips used in the mass transfer process of the micro light-emitting diode display can be solder or anisotropic conductive film (ACF). Since conventional anisotropic conductive film has to be pressurized in order to achieve an electrical connection during the mass transfer process, the electrode film can crack due to the pressure, thereby interrupting the electric connection of the micro light-emitting diode. In addition, since solder is not viscous at room temperature, the solder cannot be used to temporarily bond the micro light-emitting diode transferred by the mass transfer process.

Therefore, a novel method for fabricating the micro light-emitting diode display is desired to solve the aforementioned problems.

### BRIEF SUMMARY

According to embodiments of the disclosure, the disclosure provides a conductive composition. The conductive composition includes a monomer, a conductive powder, and an epoxy resin. The monomer has a weight W1 of 5 to 90 parts by weight, wherein the monomer has n reactive functional groups, and n is 1, 2, 3 or 4. The monomer has a molecular weight equal to or less than 350. The epoxy resin has a weight W2 of 10 to 95 parts by weight. The epoxy resin has an epoxy equivalent weight (EEW) from 160 g/Eq to 3500 g/Eq. The conductive powder has a weight of 50 to 150 parts by weight. The total weight (W1+W2) of the monomer and the epoxy resin is 100 parts by weight. The weight W1, the number n, the molecular weight Mw1, the weight W2, and the epoxy equivalent weight (EEW) satisfy the following relationship:

16.90≤Ln[(EEW²)×(Mw1/n)×(W2/(W1+W2)]≤18.90.

According to embodiments of the disclosure, the disclosure provides a method for fabricating a micro light-emitting diode display device. The method includes the following steps: providing a display substrate, wherein the display substrate has a plurality of contact pads disposed on the top surface of the display substrate; forming a film of the conductive composition of the disclosure on the top surface of the display substrate, wherein the film covers the contact pad; providing a carrier, wherein a plurality of micro light-emitting diodes are disposed on the carrier, and each micro light-emitting diode has an electrode; transferring the micro light-emitting diodes to the display substrate, wherein each micro light-emitting diode is bonded on the corresponding contact pad via the film; subjecting the film to a first thermal treatment so that the conductive powder of the film forms a conductive layer, and the electrode of the micro light-emitting diode is electrically connected to the contact pad via the conductive layer; and, subjecting the film to a second thermal treatment.

### BRIEF DESCRIPTION OF THE DRAWINGS

A detailed description is given in the following embodiments with reference to the accompanying drawings. It should be emphasized that many features are not drawn to scale according to standard practice in the industry. In fact, the dimensions of the various components may be arbitrarily increased or decreased for clarity of discussion.

FIG. 1 is a flow chart illustrating a method for fabricating the micro light-emitting diode display device according to an embodiment of the disclosure.

FIG. 2 is a schematic diagram of the display substrate having a plurality of contact pads according to an embodiment of the disclosure.

FIG. 3 is a schematic diagram of the display substrate having a film of the conductive composition according to an embodiment of the disclosure.

FIG. 4 is a schematic diagram of the carrier having a plurality of micro light-emitting diodes according to an embodiment of the disclosure.

FIG. 5 is a schematic diagram showing the step for transferring the plurality of micro light-emitting diodes to the display substrate according to an embodiment of the disclosure.

FIG. 6 is a schematic diagram showing the step for subjecting the film to a first thermal treatment according to an embodiment of the disclosure.

FIG. 7 is a graph plotting the logarithm of the viscosity of Epikote 1001 (epoxy resin) against the logarithm of temperature.

FIG. 8 is a graph plotting the logarithm of the viscosity of Epikote 1003 (epoxy resin) against the logarithm of temperature.

FIG. 9 is a graph plotting the logarithm of the viscosity of Epikote 1007 (epoxy resin) against the logarithm of temperature.

FIG. 10 is a graph plotting the logarithm of the viscosity of Epikote 1009 (epoxy resin) against the logarithm of temperature.

FIG. 11 is a graph plotting the logarithm of the viscosity of EPICLON HP-4700 (epoxy resin) against the logarithm of temperature.

### DETAILED DESCRIPTION

The conductive composition and method for fabricating a micro light-emitting diode display device of the disclosure are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

It should be noted that the elements or devices in the drawings of the disclosure may be present in any form or configuration known to those skilled in the art. In addition, the expression “a layer overlying another layer”, “a layer is disposed above another layer”, “a layer is disposed on another layer” and “a layer is disposed over another layer” may refer to a layer that directly contacts the other layer, and they may also refer to a layer that does not directly contact the other layer, there being one or more intermediate layers disposed between the layer and the other layer.

The drawings described are only schematic and are non-limiting. In the drawings, the size, shape, or thickness of some of the elements may be exaggerated and not drawn on scale for illustrative purposes. The dimensions and the relative dimensions do not correspond to actual location to practice of the disclosure. The disclosure will be described with respect to particular embodiments and with reference to certain drawings but the disclosure is not limited thereto.

Moreover, the use of ordinal terms such as “first”, “second”, “third”, etc., in the disclosure to modify an element does not by itself connote any priority, precedence, or order of one claim element over another or the temporal order in which it is formed, but are used merely as labels to distinguish one claim element having a certain name from another element having the same name (but for use of the ordinal term) to distinguish the claim elements.

The disclosure provides a conductive composition and a method for fabricating a micro light-emitting diode display device employing the conductive composition. After coating the conductive composition of the disclosure on a substrate to form a film, the film can have an adhesion force (at room temperature) against to the substrate of 90 gf/25 mm to 2000 gf/25 mm. Therefore, the film, serving as an anisotropic conductive adhesive, can be disposed on a display substrate and be used to temporarily bond the micro light-emitting diode, which is transferred from a carrier, on the display substrate at room temperature. As a result, the alignment between the micro light-emitting diode and the contact pad of the display substrate can be improved. In addition, while the film prepared from the conductive composition of the disclosure is subjected to a first thermal treatment to form a conductive layer consisting of the conductive powder, the organic portion (i.e. the other components except for the conductive powder (or the conductive layer made of the conductive powder)) exhibits a viscosity less than or equal to 0.1 Pa·s. As a result, during the first thermal treatment, the conductive powder (or molten conductive powder) can freely move within the film so that the conductive powder may be self-assembled to form the conductive film between the electrode of the micro light-emitting diode and the contact pad due to surface tension difference. The self-alignment of the conductive film is achieved. In addition, the first thermal treatment can form an electrical connection between the micro light-emitting diode and the contact pad of the display substrate without curing the film. As a result, the micro light-emitting diode of the display substrate can be subjected to a detection process, thereby identifying whether a faulty micro light-emitting diode is present or not. Thus, the faulty micro light-emitting diode is replaced with a known good micro light-emitting diode after repeating the first thermal treatment to remove the faulty micro light-emitting diode.

According to embodiments of the disclosure, the conductive composition of the disclosure can include a monomer, an epoxy resin and a conductive powder. The monomer has a weight W1 of 5 to 90 parts by weight, such as 10 to 90 parts by weight, 10 to 80 parts by weight 10 to 70 parts by weight. The monomer has n reactive functional groups, and n is 1, 2, 3, or 4. The epoxy resin has a weight W2 of 10 to 95 parts by weight, such as 10 to 90 parts by weight, 20 to 90 parts by weight 20 to 80 parts by weight. The total weight (W1+W2) of the monomer and the epoxy resin is 100 parts by weight. The monomer has a molecular weight equal to or less than 350. The epoxy resin has an epoxy equivalent weight (EEW) from 160 g/Eq to 3500 g/Eq. The conductive powder has a weight of 50 to 150 parts by weight, such as 50 to 100 parts by weight.

It should be noted that, the weight (W1) of monomer, the number (n) of reactive functional group of monomer, the molecular weight (Mw1) of monomer, the weight (W2) of epoxy resin, and the epoxy equivalent weight (EEW) of epoxy resin satisfy the following Equation (I):

16.90≤T=Ln[(EEW²)×(Mw1/n)×(W2/(W1+W2))]≤518.90 Equation (I)

According to some embodiments of the disclosure, 16.905≤T≤518.30. According to other embodiments of the disclosure, 16.965≤T≤518.28.

When the T value is less than 16.90, the film prepared from the conductive composition (non-curing) exhibits insufficient viscosity at room temperature. Therefore, the film cannot temporarily bond the micro light-emitting diode at room temperature, resulting in misalignment between the micro light-emitting diode and the contact pad of the display substrate. In addition, when the T value (T=Ln[(EEW²)×(Mw1/n)×(W2/(W1+W2))) is greater than 18.90, the organic portion (i.e. the other components of the film except the conductive powder (or the conductive layer made of the conductive powder)) of the film would have a relatively high viscosity (greater than 0.1 Pa·s) after subjecting the film of the conductive composition (coated on the display substrate without curing) to a first thermal treatment in order to melt the conductive powder. A s a result, the conductive powder (or molten conductive powder) cannot freely move within the film due to the low surface tension difference, and the self-alignment of the conductive film would not be achieved (i.e. there is no uninterrupted conductive layer formed between the light-emitting diode and the contact pad).

According to embodiments of the disclosure, the specific relationship of the weight (W1) of monomer, the number (n) of reactive functional group of monomer, the molecular weight (Mw1) of monomer, the weight (W2) of epoxy resin, and the epoxy equivalent weight (EEW) of epoxy resin is designed and qualified based on the monomer having a molecular weight (Mw1) greater than or equal to 350 and the epoxy having an epoxy equivalent weight (EEW) from 160 g/Eq to 3500 g/Eq. Even if the properties of other monomer (i.e. the monomer has a molecular weight (Mw1) greater than 350) and other epoxy (i.e. the epoxy has an epoxy equivalent weight (EEW) less than 160 g/Eq, or greater than 3500 g/Eq) meet the aforementioned relationship (16.90≤Ln[(EEW²)×(Mw1/n)×(W2/(W1+W2))]≤18.90) defined in Equation (I), the obtained conductive composition cannot achieve the above-mentioned aims of the disclosure.

According to embodiments of the disclosure, the monomer can be a monomer having one reactive functional group, a monomer having two reactive functional groups, or a monomer having three reactive functional groups. The reactive functional group of the monomer can be oxiranyl group, cyclohexene oxide group, oxetanyl group, vinyloxy group, allyloxy group, acrylate group, or methacrylate group. When the monomer is a monomer having two reactive functional groups or a monomer having three reactive functional groups, each reactive functional group can be independently oxiranyl group, oxetanyl group, vinyloxy group, allyloxy group, acrylate group, or methacrylate group.

According to embodiments of the disclosure, the monomer is trimethylolethane-oxetane, trimethylolpropane oxetane, trimethylolbutane oxetane, trimethylolpentane oxetane, trimethylolhexane oxetane, trimethylolheptane oxetane, trimethyloloctane oxetane, trimethylolnonane oxetane, ethylene glycol diglycidyl ether, propylene glycol diglycidyl ether, butanediol diglycidyl ether, neopentyl glycol diglycidyl ether, hexanediol diglycidyl ether, cyclohexanedimethanol diglycidyl ether, bisphenol A diglycidyl ether (BADGE), bisphenol F diglycidyl ether (BFDGE), terephthalic acid diglycidyl ester, tetrahydrophthalic acid diglycidyl ester, hexahydrophthalic acid diglycidyl ester, triglycidyl p-aminophenol, triglycidyl isocyanurate, trimethylolpropane triglycidyl ether, glycerol triglycidyl ether, or a combination thereof.

According to embodiments of the disclosure, the conductive composition of the disclosure can merely employ a single type of monomer. According to other embodiments of the disclosure, the conductive composition of the disclosure can employ at least two types of monomers. When the conductive composition of the disclosure employs at least two types of monomers, the molecular weight (Mw1) in Equation (I) means the weighted average molecular weight of the at least two monomers, and the weight (W1) means the total weight of the at least two monomers. In addition, when the conductive composition of the disclosure employs at least two types of monomers, the number (n) of reactive functional group means the number of weighted average reactive functional group of the at least two types of monomers.

According to embodiments of the disclosure, the epoxy resin has a weight average molecular weight (Mw2) from 500 to 7000, and the epoxy resin has an epoxy equivalent weight (EEW) from 160 g/Eq to 3500 g/Eq, wherein the epoxy equivalent weight of the epoxy resin is determined by a method described in JIS K-7236.

According to embodiments of the disclosure, the epoxy resin of the disclosure meets the following requirement: a slope determined by linear regression of a plot of the logarithm of viscosity (Pa·s) of the epoxy resin against the logarithm of temperature (° C.) is between −8 and −20. The initial temperature (T) for measuring the viscosity of the epoxy resin is determined via the viscosity. The temperature, which the viscosity of the epoxy resin is between 700 Pa·s and 5000 Pa·s, may be set as the initial temperature (T). Next, the viscosity of the epoxy resin is measured every 10° C. increase for a total of 4-10 times. The viscosity of the film prepared by conductive composition (without the conductive powder and solvent) was determined at 140° C. (under a shear rate of 10 s⁻¹, a gap of 200 μm and a plate length of 25 mm) via a dynamic rheometer (AR-G2, from TA instruments). The plot of the logarithm of measured epoxy resin viscosity (log 10 V) against the logarithm of temperature (log 10 T) is generated. When the slope determined by linear regression of a plot of the logarithm of viscosity (Pa·s) of the epoxy resin against the logarithm of temperature (° C.) is not between −8 and −20, the film prepared from the conductive composition (non-curing) exhibits insufficient viscosity at room temperature. Therefore, the film cannot temporarily bond the micro light-emitting diode at room temperature. Herein, the logarithm is a base-ten logarithm.

According to embodiments of the disclosure, the logarithm of the viscosity (Pa·s) of the epoxy resin at initial temperature (T° C.) is defined as V1, the logarithm of the viscosity (Pa·s) of the epoxy resin at initial temperature plus 10 degree (T+10° C.) is defined as V2, the logarithm of the viscosity (Pa·s) of the epoxy resin at initial temperature plus 20 degree (T+20° C.) is defined as V3, and the logarithm of the viscosity (Pa·s) of the epoxy resin at initial temperature plus 30 degree (T+30° C.) is defined as V4, wherein V1 is from 2.84 to 3.70, V1>V2>V3>V4, and V1-V4≥1.83. According to embodiments of the disclosure, V1, V2, V3 and V4 satisfy one of the following relationships (1) and (2):

2.84≤V1<3,0<V4<1, and 1≤V2<2, or 1≤V3<2; and (1)

3≤V1<3.70,0.5≤V4<2, and 2≤V2<3, or 1V3<3. (2)

According to embodiments of the disclosure, the epoxy resin can be bisphenol A epoxy resin, bisphenol F epoxy resin, bisphenol S epoxy resin, novolac epoxy resin, naphthyl group epoxy resin (naphthalene-based epoxy resin), anthracene-based epoxy resin, bisphenol A diglycidyl ether (BADGE) epoxy resin (bisphenol A diglycidyl ether (BADGE) epoxy resin), ethylene glycol diglycidyl ether (EGDGE) epoxy resin, propylene glycol diglycidyl ether (PGDGE) epoxy resin, 1,4-butanediol diglycidyl ether (BDDGE) epoxy resin, or a combination thereof. For example, the epoxy resin can have a structure represented by

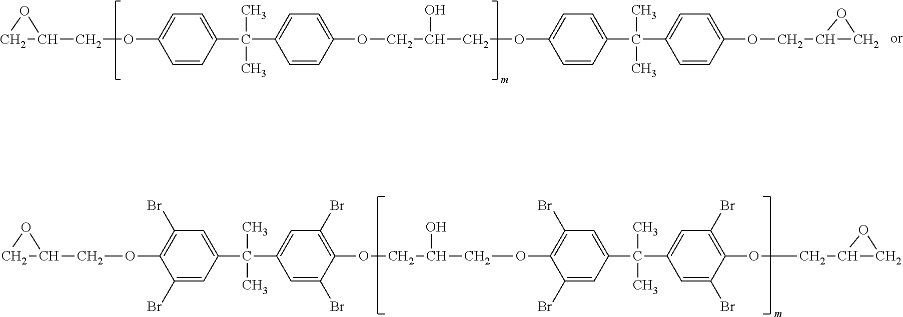

wherein m≥0.

According to embodiments of the disclosure, the epoxy resin of the disclosure can be Epikote 1001 (commercially available from Mitsubishi Chemicals Corp, having a structure of

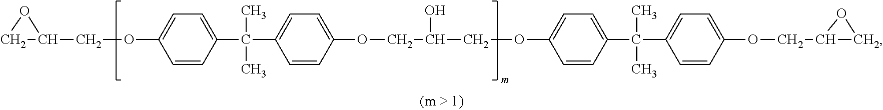

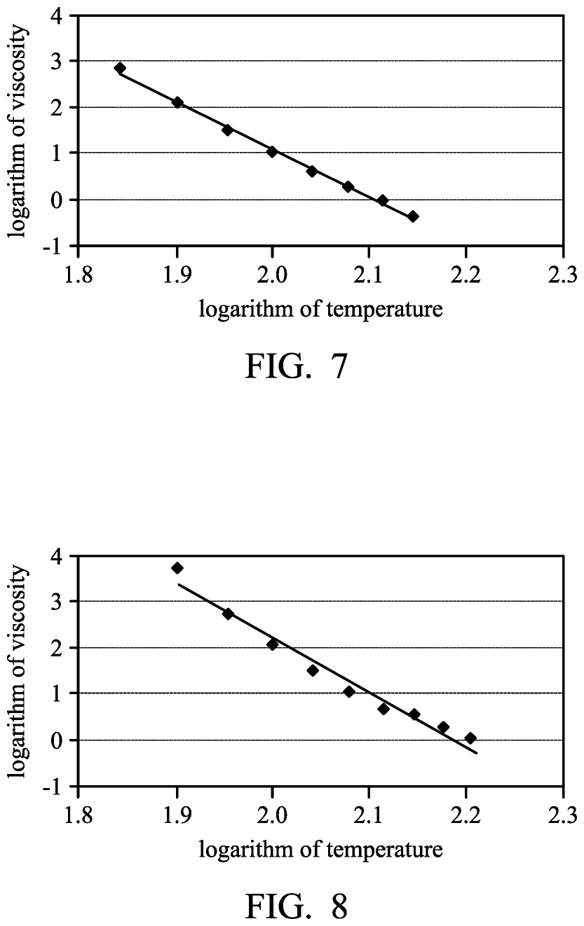

with a molecular weight of about 900). FIG. 7 is a graph plotting the logarithm of the viscosity of Epikote 1001 against the logarithm of temperature. The initial temperature for measuring the viscosity of Epikote 1001 is set as 70° C., and the viscosity of Epikote 1001 at the initial temperature is about 704.768 Pa·s. Next, the viscosity of epoxy resin is measured every 10° C. increase for a total of 7 times. The logarithm of the viscosity of Epikote 1001 at 70° C., 80° C., 90° C., and 100° C. is shown in Table 1. The slope determined by linear regression of a plot of the logarithm of viscosity of Epikote 1001 against the logarithm of temperature is −10.476, and the viscosity difference of Epikote 1001 from 70° C. to 100° C. is about 694.04 Pa·s.

TABLE 1

Epikote 1001

| | viscosity | logarithm |
|---|---|---|
| | (Pa · s) | of viscosity |
| 70° C. | 704.76842 | 2.84804644 |
| 80° C. | 122.9 | 2.08955188 |
| 90° C. | 30.693167 | 1.4870417 |
| 100° C. | 9.96625 | 0.99853178 |

According to embodiments of the disclosure, the epoxy resin of the disclosure can be Epikote 1003 (commercially available from Mitsubishi Chemicals Corp, having a structure of

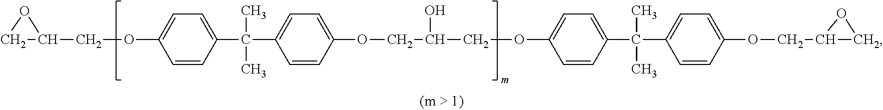

with a molecular weight of about 1300). FIG. 8 is a graph plotting the logarithm of the viscosity of Epikote 1003 against the logarithm of temperature. The initial temperature for measuring the viscosity of Epikote 1003 is set as 80° C., and the viscosity of Epikote 1003 at the initial temperature is about 4800 Pa·s. Next, the viscosity of epoxy resin is measured every 10° C. increase for a total of 7 times. The logarithm of the viscosity of Epikote 1001 at 80° C., 90° C., 100° C., and 110° C. is shown in Table 2. The slope determined by linear regression of a plot of the logarithm of viscosity of Epikote 1003 against the logarithm of temperature is −15.159, and the viscosity difference of Epikote 1003 from 80° C. to 110° C. is about 694.04 Pa·s.

TABLE 2

Epikote 1003

| | viscosity | logarithm |
|---|---|---|
| | (Pa · s) | of viscosity |
| 80° C. | 4800.381 | 3.681276 |
| 90° C. | 515.8 | 2.712481 |
| 100° C. | 110.3048 | 2.042594 |
| 110° C. | 30.59222 | 1.485611 |

According to embodiments of the disclosure, the epoxy resin of the disclosure can be Epikote 1007 (commercially available from Mitsubishi Chemicals Corp, having a structure of

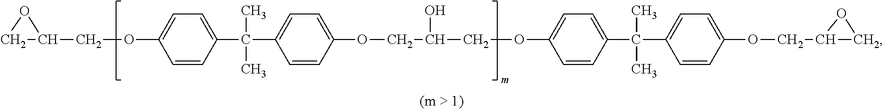

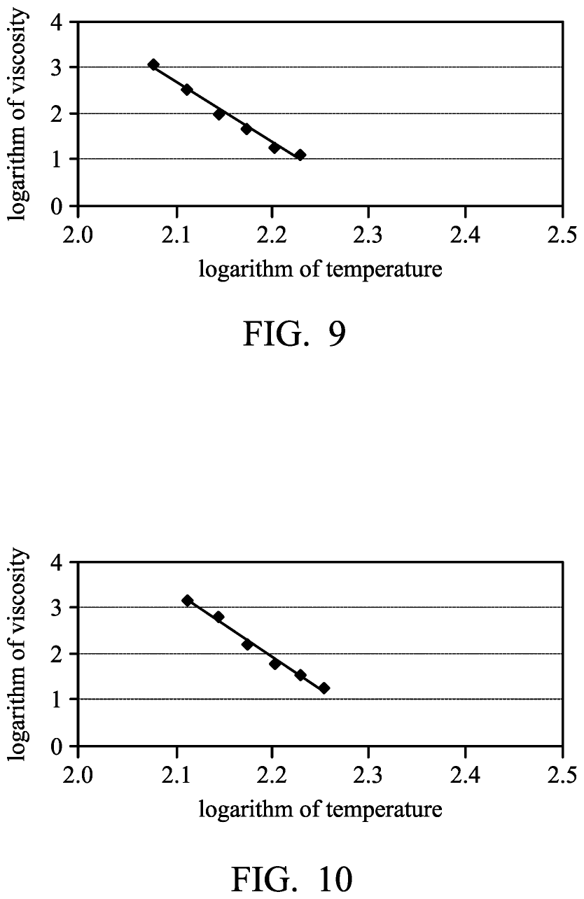

with a molecular weight of about 2900). FIG. 9 is a graph plotting the logarithm of the viscosity of Epikote 1007 against the logarithm of temperature. The initial temperature for measuring the viscosity of Epikote 1007 is set as 120° C., and the viscosity of Epikote 1007 at the initial temperature is about 1037 Pa·s. Next, the viscosity of epoxy resin is measured every 10° C. increase for a total of 7 times. The logarithm of the viscosity of Epikote 1007 at 120° C., 130° C., 140° C., and 150° C. is shown in Table 3. The slope determined by linear regression of a plot of the logarithm of viscosity of Epikote 1007 against the logarithm of temperature is −13.765, and the viscosity difference of Epikote 1007 from 120° C. to 150° C. is about 991 Pa·s.

TABLE 3

Epikote 1007

| | viscosity | logarithm |
|---|---|---|
| | (Pa · s) | of viscosity |
| 120° C. | 1037.691 | 3.016068 |
| 130° C. | 306.9569 | 2.487077 |
| 140° C. | 93.526 | 1.970932 |
| 150° C. | 46.00762 | 1.66283 |

According to embodiments of the disclosure, the epoxy resin of the disclosure can be Epikote 1009 (commercially available from Mitsubishi Chemicals Corp, having a structure of

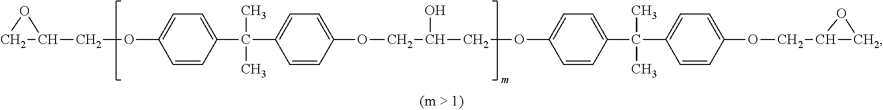

with a molecular weight of about 3800). FIG. 10 is a graph plotting the logarithm of the viscosity of Epikote 1009 (epoxy resin) against the logarithm of temperature. The initial temperature for measuring the viscosity of Epikote 1009 is set as 130° C., and the viscosity of Epikote 1009 at the initial temperature is about 1372 Pa·s. Next, the viscosity of epoxy resin is measured every 10° C. increase for a total of 6 times. The logarithm of the viscosity of Epikote 1009 at 130° C., 140° C., 150° C., and 160° C. is shown in Table 4. The slope determined by linear regression of a plot of the logarithm of viscosity of Epikote 1009 against the logarithm of temperature is −13.471, and the viscosity difference of Epikote 1009 from 130° C. to 160° C. is about 1311.06 Pa·s.

TABLE 4

Epikote 1009

| | viscosity | logarithm |
|---|---|---|
| | (Pa · s) | of viscosity |
| 130° C. | 1372 | 3.137354 |
| 140° C. | 612.8022 | 2.78732 |
| 150° C. | 161.3183 | 2.207684 |
| 160° C. | 60.94706 | 1.784953 |

According to embodiments of the disclosure, the epoxy resin of the disclosure can be EPICLON HP-4700 (commercially available from DIC, having a structure of

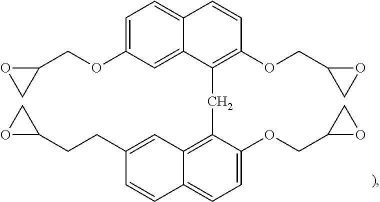 [SMILES: c1cc2ccc(OCC3CO3)c(Cc3c(OCC4CO4)ccc4ccc(OCC5CO5)cc34)c2cc1CCC1CO1]

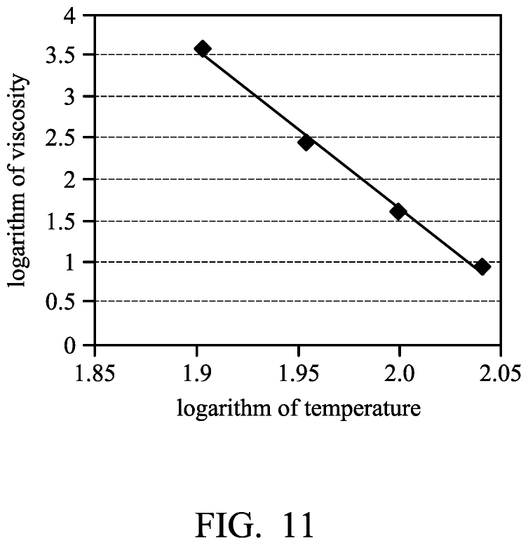

with a molecular weight of about 660. FIG. 11 is a graph plotting the logarithm of the viscosity of EPICLON HP-4700 (epoxy resin) against the logarithm of temperature. The initial temperature for measuring the viscosity of EPICLON HP-4700 is set as 80° C., and the viscosity of EPICLON HP-4700 at the initial temperature is about 1372 Pa·s. Next, the viscosity of epoxy resin is measured every 10° C. increase for a total of 6 times. The logarithm of the viscosity of EPICLON HP-4700 at 80° C., 90° C., 100° C., and 110° C. is shown in Table 5. The slope determined by linear regression of a plot of the logarithm of viscosity of EPICLON HP-4700 against the logarithm of temperature is −13.471, and the viscosity difference of EPICLON HP-4700 from 80° C. to 110° C. is about 3770 Pa·s.

TABLE 5

EPICLON HP-4700

| | viscosity | logarithm |
|---|---|---|
| | (Pa · s) | of viscosity |
| 80° C. | 3781.516 | 3.577666 |
| 90° C. | 276.1 | 2.441066 |
| 100° C. | 40.04786 | 1.602579 |
| 110° C. | 8.552318 | 0.932084 |

According to embodiments of the disclosure, the conductive composition of the disclosure can employ a single type of epoxy resin. According to other embodiments of the disclosure, the conductive composition of the disclosure can employ at least two types of epoxy resin. When the conductive composition of the disclosure employs at least two types of epoxy resin, the epoxy equivalent weight (EEW) means the weighted average epoxy equivalent weight of the two types of epoxy resin, and the weight (W2) means the total weight of the two types of epoxy resin.

According to embodiments of the disclosure, the conductive powder can be a welding material, such as tin-bismuth alloy, tin-indium alloy, tin-bismuth-indium alloy, tin-bismuth-antimony alloy, tin-silver-bismuth alloy, tin-copper-bismuth alloy, tin-silver-copper-bismuth alloy, tin-silver-indium alloy, tin-copper-indium alloy, tin-copper-silver-indium alloy, tin-gold-copper-bismuth-indium alloy, or a combination thereof. According to embodiments of the disclosure, the conductive powder can be tin-bismuth alloy.

According to embodiments of the disclosure, the conductive powder can have a lower melting point than the curing temperature of the conductive composition, in order to prevent the conductive composition from curing during heating the conductive powder to a molten state by a first thermal treatment.

According to embodiments of the disclosure, the temperature difference between the melting point of the conductive powder and the curing temperature of the conductive composition is equal to or greater than 20° C., such as equal to or greater than 30° C., equal to or greater than 40° C., or equal to or greater than 50° C. According to embodiments of the disclosure, the conductive powder has a melting point from 130° C. to 160° C., such as 140° C., 150° C., or 160° C.

According to embodiments of the disclosure, the conductive powder can have an average particle size from 1 μm to 100 μm, such as 1 μm to 90 μm, 1 μm to 80 μm, 1 μm to 70 μm, 10 μm to 50 μm, or 10 μm to 20 μm.

According to embodiments of the disclosure, the conductive composition can further include a deoxidizer, wherein the deoxidizer is 1-40 parts by weight. According to embodiments of the disclosure, the deoxidizer can be pentanedioic acid, decanedioic acid, suberic acid, adipic acid, methylsuccinic acid, salicylic acid, stearic acid, succinic anhydride, benzoic acid, tartaric acid, itaconic acid, dodecanoic acid, myristic acid, palmitic acid, ethanolamine, ethylenediamine, butanediolamine, diethylenetriamine, 3-propanolamine, hydroxyethylenediamine, ammonium succinate, N,N-diethylethanolamine, or a combination thereof.

According to embodiments of the disclosure, the conductive composition can further include a hardener, wherein the hardener can be 0.01-10 parts by weight. The hardener can be iodinium salt, sulfonium salt, or a combination thereof. For example, the iodinium salt can be diphenyliodonium tetrafluoroborate, di(4-methylphenyl)iodonium tetrafluoroborate, phenyl-4-methylphenyliodonium tetrafluoroborate, di(4-heptylphenyl)iodonium tetrafluoroborate, di(3-nitrophenyl)iodonium hexafluorophosphate, or di(4-chlorophenyl)iodonium hexafluorophosphate; and, sulfonium salt can be triphenylsulfonium tetrafluoroborate, methyldiphenylsulfonium tetrafluoroborate, dimethylphenylsulfonium hexafluorophosphate, triphenylsulfonium hexafluorophosphate, triphenylsulfonium hexafluoroantimonate, diphenylnaphthylsulfonium hexafluoroarsenate, tritolysulfonium hexafluorophosphate, anisyldiphenylsulfonium hexafluoroantimonate, 4-butoxyphenyldiphenylsulfonium tetrafluoroborate, 4-chlorophenyldiphenyl-sulfonium hexafluorophosphate, or tri(4-phenoxyphenyl)sulfonium hexafluorophosphate. According to embodiments of the disclosure, the conductive composition can further include a solvent, and thus the monomer, epoxy resin, conductive powder, deoxidizer, and hardener can be dissolved and uniformly dispersed in the solvent. The solvent can be methyl ethyl ketone, propylene glycol methyl ether acetate (PGMEA), isopentyl acetate, benzene, toluene, xylene, cyclohexane, or a combination thereof.

According to embodiments of the disclosure, the conductive composition can have a solid content (i.e. the weight percentage of all components except the solvent of the conductive composition, based on the weight of the conductive composition) from 5 wt % to 90 wt %.

According to embodiments of the disclosure, the conductive composition can be used to form a film, such as an anisotropic conductive film. The method for forming the film can include following steps. The conductive composition is coated on a substrate to form a coating. Next, the coating is subjected to a baking process to remove the solvent of the conductive composition, thereby forming a film. The method for coating the conductive composition on the substrate can be screen printing, stencil printing, spin coating, bar coating, blade coating, roller coating, dip coating, spray coating, or brush coating.

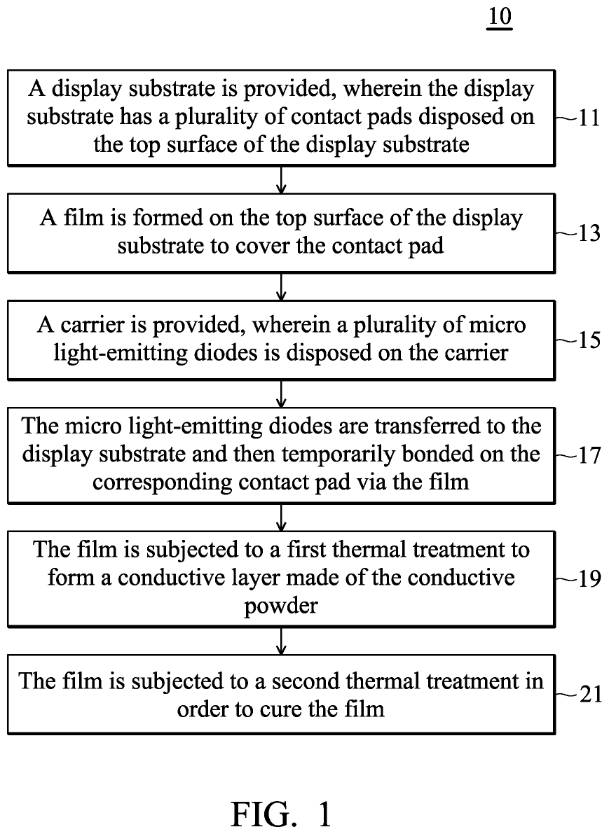

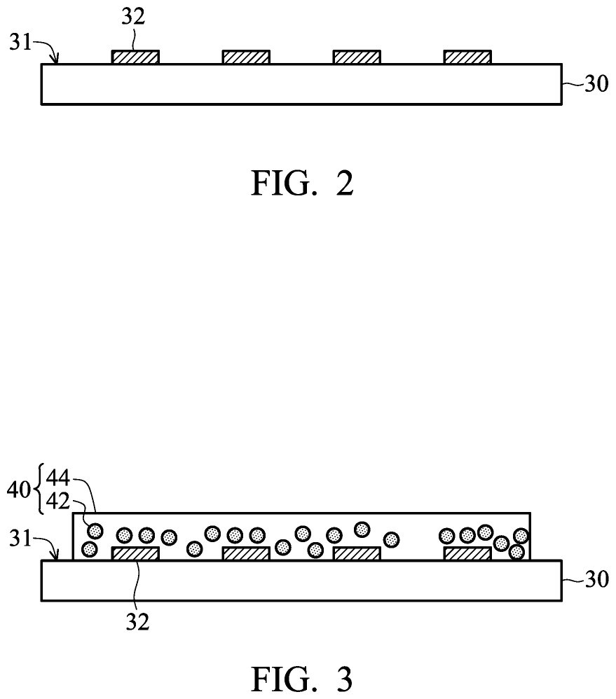

According to embodiments of the disclosure, the disclosure provides a method for fabricating a micro light-emitting diode display device. FIG. 1 is a flow chart illustrating a method for fabricating the micro light-emitting diode display device 10 according to an embodiment of the disclosure. FIGS. 2-6 are a series of diagrams showing the method for fabricating the micro light-emitting diode display device 10 of the disclosure. First, as shown in FIG. 2, a display substrate 30 is provided, wherein the display substrate has a plurality of contact pads 32 disposed on the top surface 31 of the display substrate 30 (step 11).

Next, as shown in FIG. 3, a film 40 is formed on the top surface 31 of the display substrate 30 to cover the contact pad 32 (step 13). The film 40 is made of the aforementioned conductive composition. The method for forming the film 40 can include coating the conductive composition on a substrate to form a film and then subjecting the film to a baking process to remove the solvent of the conductive composition, thereby forming the film 40. According to embodiments of the disclosure, the film 40 consists of the conductive powder 42 and the organic portion 44 (i.e. the components of the conductive composition except the conductive powder). The film 40 can be a continuous film, as shown in FIG. 3. According to embodiments of the disclosure, the film 40 can be a non-continuous film. For example, the film can be a patterned film including a plurality of regions, wherein each region covers a corresponding contact pad, and two adjacent regions are separated by a predetermined distance.

According to embodiments of the disclosure, the monomer of the conductive composition would not react with the epoxy resin during the baking process (i.e. the conductive composition is not cured by the baking process). According to embodiments of the disclosure, the temperature of the baking process can be from 50° C. to 100° C.

According to embodiments of the disclosure, the film has a peeling strength greater than 90 gf/25 mm, wherein the peeling strength is determined by a method described in ASTM-D1876.

According to embodiments of the disclosure, an adhesion force between the film and the substrate at room temperature is from 90 gf/25 mm to 2000 gf/25 mm, wherein the adhesion force is determined by a method described in ASTM-D1876.

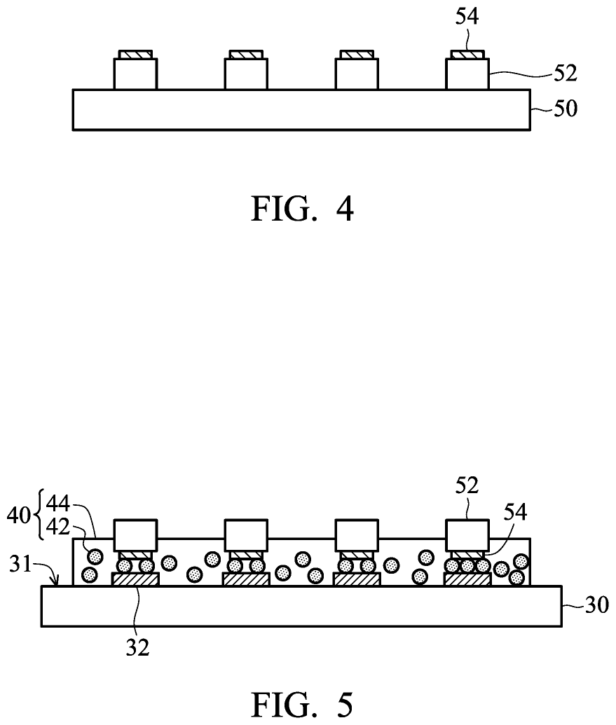

Next, as shown in FIG. 4, a carrier 50 is provided, wherein a plurality of micro light-emitting diodes 52 is disposed on the carrier 50, wherein each micro light-emitting diode 52 has an electrode 54 (step 15). According to embodiments of the disclosure, the micro light-emitting diode of the disclosure means a light-emitting diode which has a length, width and height within a range of 1 μm to 100 μm. According to embodiments of the disclosure, the light-emitting diode may have a maximum width of 20 μm, 10 μm, or 5 μm. In some embodiments, the light-emitting diode may have a maximum height of 10 μm or 5 μm. However, it should be understood that embodiments of the present disclosure are not limited thereto, and aspects of certain embodiments may be applied to larger and perhaps smaller scales. According to embodiments of the disclosure, the micro light-emitting diode 52 can be a perpendicular type light-emitting diode or horizontal type light-emitting diode. When the micro light-emitting diode 52 is a perpendicular type light-emitting diode, the micro light-emitting diode 52 can have another electrode opposite to the electrode 54. When the micro light-emitting diode 52 is a horizontal type light-emitting diode, the micro light-emitting diode 52 can have another electrode and the another electrode and the electrode 54 are disposed on the same side of the micro light-emitting diode 52. The other electrode is not shown in diagrams for convenience of illustration.

Next, as shown in FIG. 5, the micro light-emitting diodes 52 are transferred to the display substrate 30 and then temporarily bonded on the corresponding contact pad 32 via the film 40 (step 17). According to embodiments of the disclosure, the micro light-emitting diodes 52 may be transferred from the carrier 50 to the display substrate 30 via a transfer process (such as a mass transfer process). The mass transfer process can be performed to transfer the micro light-emitting diode 52 from the carrier 50 to the display substrate 30 one at a time or in a batch. For example, methods of mechanical electrostatic attraction, vacuum drawing or adhesion by adhesive tape are used to perform the transfer process. Since the adhesion force between the film 40 and the display substrate 30 at room temperature is from 90 gf/25 mm to 2000 gf/25 mm, the micro light-emitting diode 52 may be temporarily bonded on the corresponding contact pad 32 via the film 40 prepared from the conductive composition, thereby facilitating the transfer of the micro light-emitting diode 52 from the carrier 50 to the display substrate 30.

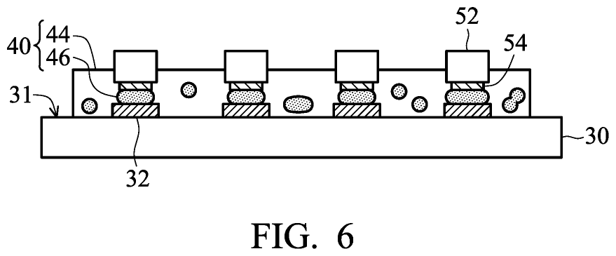

Next, as shown in FIG. 6, the film 40 is subjected to a first thermal treatment to melt the conductive powder 42 of the film 40, wherein the molten conductive powder is self-assembled between the electrode 54 of the micro light-emitting diode 52 and the contact pad 32 due to the surface tension thereof, and then the molten conductive powder is formed a conductive layer 46 after cooling (step 19). Herein, the electrode 54 of the micro light-emitting diode 52 is electrically connected to the contact pad 32 via the conductive layer 46. According to embodiments of the disclosure, while the first thermal treatment is performed to convert the conductive powder 42 of the film 40 to a conductive layer 46, the organic portion 44 (i.e. the other components of the film except the conductive powder (or the conductive layer made of the conductive powder)) of the film 40 has an viscosity is less than or equal to 0.1 Pa·s. As a result, during the first thermal treatment, the conductive powder 42 (or molten conductive powder) can freely move within the film so that the conductive powder may be self-assembled to form the conductive film 46 between the electrode 54 of the micro light-emitting diode 52 and the contact pad 32 due to surface tension difference. As a result, the self-alignment of the conductive film 46 is achieved.

According to embodiments of the disclosure, the temperature of the first thermal treatment may be equal to or greater than the melting point of the conductive powder, therefore converting the conductive powder to the conductive layer. As a result, the electrode 54 of the micro light-emitting diode 52 is electrically connected to the contact pad 32 via the conductive layer 46. According to embodiments of the disclosure, the temperature of the first thermal treatment is 0.5° C.-25° C. higher than the melting point of the conductive powder. According to embodiments of the disclosure, during the first thermal treatment, the film 40 would not be cured (i.e. the monomer would not react with the epoxy resin). According to embodiments of the disclosure, the temperature of the first thermal treatment can be from 130° C. to 160° C.

According to embodiments of the disclosure, after electrically connecting the electrode 54 of the micro light-emitting diode 52 to the contact pad 32 of the display substrate 30 via the first thermal treatment, the micro light-emitting diode 52 on the display substrate 30 may be subjected to a detection process, thereby identifying whether a faulty micro light-emitting diode is present or not. Since the first thermal treatment would not cure the film 40, the faulty micro light-emitting diode can be removed by subjecting the conductive layer 46 (disposed under the faulty micro light-emitting diode) to the first thermal treatment and then replaced with a known good micro light-emitting diode.

According to embodiments of the disclosure, the purpose of the detection process is to identify whether any defect or flaw in the micro light-emitting diode is present or not before performing the second thermal treatment (for curing the film 40). As a result, the faulty light-emitting diode can be identified and then repaired before the micro light-emitting diode display device assembly. According to embodiments of the disclosure, the detection process can be an electrical detection process.

Finally, the film 40 is subjected to a second thermal treatment to cure the film 40 (step 21). As a result, the micro light-emitting diode 52 can be permanently bonded on the display substrate 30. According to embodiments of the disclosure, the temperature of the second thermal treatment is greater than that of the first thermal treatment. According to embodiments of the disclosure, the temperature of the second thermal should promote the monomer to react with epoxy resin in the film 40. According to embodiments of the disclosure, the temperature of the second thermal treatment can be from 180° C. to 250° C.

Below, exemplary embodiments will be described in detail with reference to the accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

### Example 1

10 parts by weight of trimethylolpropane oxetane (TMPO) (commercially available from Perstorp Specialty Chemicals), 90 parts by weight of bisphenol A epoxy resin (with a trade number of Epikote 1001 and commercially available from Mitsubishi Chemicals Corp, having an epoxy equivalent weight of about 470), 15.38 parts by weight of glutaric acid), 77 parts by weight of tin-bismuth powder (with a trade number of Sn42/Bi58 and commercially available from Hanon Technology Industry Limited, having an average particle size of about 10-20 μm), 0.5 parts by weight of hardener (with a trade number of SI-B4 and commercially available from Shan-shin chemical industry CO. LTD) and 19.23 parts by weight of methyl ethyl ketone were mixed, obtaining Conductive Composition (1), wherein the weight ratio of TMPO to Epikote 1001 was 1:9. The T value of Conductive Composition (1) was determined according to Equation (I), and the results are shown in Table 6.

Next, the peeling strength of the film prepared from Conductive Composition (1) was measured, and the results are shown in Table 6. The method for measuring the peeling strength of the film prepared from the conductive composition includes the following steps. First, the conductive composition was coated on a copper foil by screen coating to form a coating. Next, the coating was baked at 80° C. to remove the solvent of the coating, obtaining a film. Next, another copper foil (with a width of 25 mm) was disposed on the film. Next, the peeling strength of the film was determined by a method described in ASTM-D1876.

Next, the viscosity of the film prepared by Conductive Composition (1) at 140° C. was measured, and the results are shown in Table 6. The viscosity of the film prepared by conductive composition (without the conductive powder and solvent) was determined at 140° C. (under a shear rate of 10 s⁻¹ and a gap of 50 μm) via a dynamic rheometer (AR-G2, from TA instruments).

Next, the film prepared from Conductive Composition (1) was heated to the melting point of the conductive powder to be subjected to a self-assembly test, and the results are shown in Table 6. The self-assembly test includes the following steps. First, a substrate was prepared, wherein the substrate had a plurality of contact pad and control circuits thereon. Next, the conductive composition was coated on the contact pad of the substrate by screen printing or stencil printing to form a coating. Next, the coating was baked at 80° C. to remove the solvent of the coating, obtaining a film. Next, the film was heated at 150° C. for 5 minutes. After cooling, the substrate was checked to determine whether a conductive layer made of the gathered conductive powder was formed on the contact pad and/or the control circuit. If the conductive layer made of the gathered conductive powder was formed to achieve an electrical connect with the contact pad and/or the control circuit, it is considered a “pass”.

Next, the film prepared by Conductive Composition (1) was subjected to a test for transferring chips, and the results are shown in Table 6. The test for transferring chips includes the following steps. First, the conductive composition was coated on a copper foil to form a coating. Next, the coating was baked at 80° C. to remove the solvent of the coating, obtaining a film. Next, 300 chips (with a size of 175 μm*125 μm) disposed on the polydimethylsiloxane (PDMS) film were transferred to the film. If all chips were transferred from the PDMS film to the film, it is considered a “pass”.

### Comparative Example 1

Comparative Example 1 was performed in the same manner as Example 1 except that the weight ratio of TMPO to Epikote 1001 was adjusted from 1:9 to 2:8, and the weight of methyl ethyl ketone was reduced from 19.23 parts by weight to 15.38 parts by weight, obtaining Conductive Composition (2). The T value of Conductive Composition (2) was determined according to Equation (I), and the results are shown in Table 6. Next, the peeling strength and the viscosity at 140° C. of the film prepared by Conductive Composition (2) were measured and the film prepared by Conductive Composition (2) was subjected to the test for transferring chips and the self-assembly test, and the results are shown in Table 6.

### Comparative Example 2

Comparative Example 1 was performed in the same manner as Example 1 except that the weight ratio of TMPO to Epikote 1001 was adjusted from 1:9 to 3:7, and the weight of methyl ethyl ketone was reduced from 19.23 parts by weight to 9.61 parts by weight, obtaining Conductive Composition (3). The T value of Conductive Composition (3) was determined according to Equation (I), and the results are shown in Table 6. Next, the peeling strength and the viscosity at 140° C. of the film prepared by Conductive Composition (3) were measured and the film prepared by Conductive Composition (3) was subjected to the test for transferring chips and the self-assembly test, and the results are shown in Table 6.

### Comparative Example 3

Comparative Example 3 was performed in the same manner as Example 1 except that the weight ratio of TWO to Epikote 1001 was adjusted from 1:9 to 4:6, and the weight of methyl ethyl ketone was reduced from 19.23 parts by weight to 5.77 parts by weight, obtaining Conductive Composition (4). The T value of Conductive Composition (4) was determined according to Equation (I), and the results are shown in Table 6. Next, the peeling strength and the viscosity at 140° C. of the film prepared by Conductive Composition (4) were measured and the film prepared by Conductive Composition (4) was subjected to the test for transferring chips and the self-assembly test, and the results are shown in Table 6.

TABLE 6

| | | Comparative | Comparative | Comparative |
|---|---|---|---|---|
| | Example 1 | Example 1 | Example 2 | Example 3 |
| TMPO | 10 | 20 | 30 | 40 |
| (parts by weight) | | | | |
| Epikote 1001 | 90 | 80 | 70 | 60 |
| (parts by weight) | | | | |
| (glutaric | 15.38 | 15.38 | 15.38 | 15.38 |
| acid)(parts by | | | | |
| weight) | | | | |
| tin-bismuth | 77 | 77 | 77 | 77 |
| powder (parts | | | | |
| by weight) | | | | |
| hardener | 0.5 | 0.5 | 0.5 | 0.5 |
| (parts by weight) | | | | |
| methyl ethyl | 19.23 | 15.38 | 9.61 | 5.77 |
| ketone (parts by | | | | |
| weight) | | | | |
| T value | 16.96 | 16.84 | 16.7 | 16.55 |
| peeling strength | 484.25 | 41.7 | 11.48 | 6.33 |
| (gf/25 mm) | | | | |
| viscosity | 0.073 | 0.035 | 0.027 | 0.039 |
| (Pa · s) | | | | |
| self-assembly | pass | pass | pass | pass |
| test | | | | |
| test for | pass | fail | fail | fail |
| transferring | | | | |
| chips | | | | |

As shown in Table 6, when the amount of TMPO (monomer was increased resulting in reducing the T value (less than 16.9), the viscosity and the peeling strength of the film prepared from the conductive composition was reduced. As a result, since the adhesion between the film and the substrate is insufficient, the film prepared from the conductive composition of Comparative Example 1-3 cannot pass the test for transferring chips.

In addition, since the film prepared from the conductive composition of Example 1 has a viscosity (at 140° C.) less than 0.1 Pa·s, the conductive powder can freely move within the film and the film of Example 1 can pass the test for transferring chips.

### Example 2

40 parts by weight of hexahydrophthalic acid diglycidyl ester (with a trade number of EPALLOY® 5200 and commercially available from CVC Specialties thermoset), 60 parts by weight of bisphenol A epoxy resin (with a trade number of Epikote 1003 and commercially available from Mitsubishi Chemicals Corp, having an epoxy equivalent weight of about 700), 15.38 parts by weight of glutaric acid, 77 parts by weight of tin-bismuth powder (with a trade number of Sn42/Bi58 and commercially available from Hanon Technology Industry Limited, having an average particle size of about 10-20 μm), 0.5 parts by weight of hardener (with a trade number of SI-B4 and commercially available from Shan-shin chemical industry CO. LTD), and 19.23 parts by weight of methyl ethyl ketone were mixed, obtaining Conductive Composition (5), wherein the weight ratio of EPALLOY® 5200 to Epikote 1003 was 4:6. The T value of Conductive Composition (5) was determined according to Equation (I), and the results are shown in Table 7. Next, the peeling strength and the viscosity at 140° C. of the film prepared by Conductive Composition (5) were measured and the film prepared by Conductive Composition (5) was subjected to the test for transferring chips and the self-assembly test, and the results are shown in Table 7.

### Example 3

Example 3 was performed in the same manner as Example 2 except that the weight ratio of EPALLOY® 5200 to Epikote 1003 was adjusted from 4:6 to 5:5, and the weight of methyl ethyl ketone was reduced from 19.23 parts by weight to 15.38 parts by weight, obtaining Conductive Composition (6). The T value of Conductive Composition (6) was determined according to Equation (I), and the results are shown in Table 7. Next, the peeling strength and the viscosity at 140° C. of the film prepared by Conductive Composition (6) were measured and the film prepared by Conductive Composition (6) was subjected to the test for transferring chips and the self-assembly test, and the results are shown in Table 7.

### Example 4

Example 4 was performed in the same manner as Example 2 except that the weight ratio of EPALLOY® 5200 to Epikote 1003 was adjusted from 4:6 to 6:4, and the weight of methyl ethyl ketone was reduced from 19.23 parts by weight to 9.67 parts by weight, obtaining Conductive Composition (7). The T value of Conductive Composition (7) was determined according to Equation (I), and the results are shown in Table 7. Next, the peeling strength and the viscosity at 140° C. of the film prepared by Conductive Composition (7) were measured and the film prepared by Conductive Composition (7) was subjected to the test for transferring chips and the self-assembly test, and the results are shown in Table 7.

### Comparative Example 4

Comparative Example 4 was performed in the same manner as Example 2 except that the weight ratio of EPALLOY® 5200 to Epikote 1003 was adjusted from 4:6 to 7:3, and the weight of methyl ethyl ketone was reduced from 19.23 parts by weight to 5.77 parts by weight, obtaining Conductive Composition (8). The T value of Conductive Composition (8) was determined according to Equation (I), and the results are shown in Table 7. Next, the peeling strength and the viscosity at 140° C. of the film prepared by Conductive Composition (8) were measured and the film prepared by Conductive Composition (8) was subjected to the test for transferring chips and the self-assembly test, and the results are shown in Table 7.

### Comparative Example 5

Comparative Example 5 was performed in the same manner as Example 2 except that the weight ratio of EPALLOY® 5200 to Epikote 1003 was adjusted from 4:6 to 8:2, and the weight of methyl ethyl ketone was reduced from 19.23 parts by weight to 2.89 parts by weight, obtaining Conductive Composition (9). The T value of Conductive Composition (9) was determined according to Equation (I), and the results are shown in Table 7. Next, the peeling strength and the viscosity at 140° C. of the film prepared by Conductive Composition (9) were measured and the film prepared by Conductive Composition (9) was subjected to the test for transferring chips and the self-assembly test, and the results are shown in Table 7.

TABLE 7

| | | | | Comparative | Comparative |
|---|---|---|---|---|---|
| | Example 2 | Example 3 | Example 4 | Example 4 | Example 5 |
| EPALLOY ®5200(parts | 40 | 50 | 60 | 70 | 80 |
| by weight) | | | | | |
| Epikote 1003 | 60 | 50 | 40 | 30 | 20 |
| (parts by weight) | | | | | |
| (glutaric | 15.38 | 15.38 | 15.38 | 15.38 | 15.38 |
| acid)(parts by | | | | | |
| weight) | | | | | |
| tin-bismuth powder | 77 | 77 | 77 | 77 | 77 |
| (parts by weight) | | | | | |
| hardener | 0.5 | 0.5 | 0.5 | 0.5 | 0.5 |
| (parts by weight) | | | | | |
| methyl ethyl ketone | 19.23 | 15.38 | 9.61 | 5.77 | 2.89 |
| (parts by weight) | | | | | |
| T value | 17.55 | 17.37 | 17.14 | 16.86 | 16.45 |
| peeling strength | 111.74 | 168.7 | 2378.6 | 44.01 | 18.8 |
| (gf/25 mm) | | | | | |
| viscosity | 0.092 | 0.079 | 0.067 | 0.015 | 0.019 |
| (Pa · s) | | | | | |
| self-assembly test | pass | pass | pass | pass | pass |
| test for | pass | pass | pass | fail | fail |
| transferring chips | | | | | |

As shown in Table 7, when T value is within the range from 16.9 to 18.9, the peeling strength of the film prepared from the conductive composition is directly proportional to the amount of monomer. Furthermore, when T value is less than 16.9 resulting in from reducing the amount of monomer, the viscosity and the peeling strength of the film prepared from the conductive composition are greatly reduced. In addition, since the viscosity (at 140° C.) of the films prepared form Examples 2-4 is less than 0.1 Pa·s, the conductive powder can freely move within the film and the films of Examples 2-4 can pass the test for transferring chips.

### Example 5

80 parts by weight of hexahydrophthalic acid diglycidyl ester (with a trade number of EPALLOY® 5200 and commercially available from CVC Specialties thermoset), 20 parts by weight of bisphenol A epoxy resin (with a trade number of Epikote 1007 and commercially available from Mitsubishi Chemicals Corp, having an epoxy equivalent weight of about 1750), 15.38 parts by weight of glutaric acid, 77 parts by weight of tin-bismuth powder (with a trade number of Sn42/Bi58 and commercially available from Hanon Technology Industry Limited, having an average particle size of about 10-20 μm), 0.5 parts by weight of hardener (with a trade number of SI-B4 and commercially available from Shan-shin chemical industry CO. LTD), and 9.62 parts by weight of methyl ethyl ketone were mixed, obtaining Conductive Composition (10), wherein the weight ratio of EPALLOY® 5200 to Epikote 1007 was 8:2. The T value of Conductive Composition (10) was determined according to Equation (I), and the results are shown in Table 8. Next, the peeling strength and the viscosity at 140° C. of the film prepared by Conductive Composition (10) were measured and the film prepared by Conductive Composition (10) was subjected to the test for transferring chips and the self-assembly test, and the results are shown in Table 8.

### Comparative Example 6

Comparative Example 6 was performed in the same manner as Example 5 except that the weight ratio of EPALLOY® 5200 to Epikote 1007 was adjusted from 8:2 to 6:4, and the weight of methyl ethyl ketone was increased from 9.62 parts by weight to 12.5 parts by weight, obtaining Conductive Composition (11). The T value of Conductive Composition (11) was determined according to Equation (I), and the results are shown in Table 8. Next, the peeling strength and the viscosity at 140° C. of the film prepared by Conductive Composition (11) were measured and the film prepared by Conductive Composition (11) was subjected to the test for transferring chips and the self-assembly test, and the results are shown in Table 8.

### Comparative Example 7

Comparative Example 7 was performed in the same manner as Comparative Example 6 except that Epikote 1007 was replaced with Epikote 1009 (bisphenol A epoxy resin and commercially available from Mitsubishi Chemicals Corp, having an epoxy equivalent weight of about 2700), obtaining Conductive Composition (12). The T value of Conductive Composition (12) was determined according to Equation (I), and the results are shown in Table 8. Next, the peeling strength and the viscosity at 140° C. of the film prepared by Conductive Composition (12) were measured and the film prepared by Conductive Composition (12) was subjected to the test for transferring chips and the self-assembly test, and the results are shown in Table 8.

### Comparative Example 8

Comparative Example 8 was performed in the same manner as Comparative Example 7 except that the weight ratio of EPALLOY® 5200 to Epikote 1009 was adjusted from 6:4 to 8:2, and the weight of methyl ethyl ketone was increased from 12.5 parts by weight to 6.34 parts by weight, obtaining Conductive Composition (13). The T value of Conductive Composition (13) was determined according to Equation (I), and the results are shown in Table 8. Next, the peeling strength and the viscosity at 140° C. of the film prepared by Conductive Composition (13) were measured and the film prepared by Conductive Composition (13) was subjected to the test for transferring chips and the self-assembly test, and the results are shown in Table 8.

TABLE 8

| | | Compar- | Compar- | Compar- |
|---|---|---|---|---|
| | | ative | ative | ative |
| | Example 5 | Example 6 | Example 7 | Example 8 |
| EPALLOY ®5200 | 80 | 60 | 60 | 70 |
| (parts by weight) | | | | |
| epoxy resin | Epikote | Epikote | Epikote | Epikote |
| (parts by weight) | 100720 | 100740 | 100940 | 100930 |
| (glutaric | 15.38 | 15.38 | 15.38 | 15.38 |
| acid)(parts by | | | | |
| weight) | | | | |
| tin-bismuth powder | 77 | 77 | 77 | 77 |
| (parts by weight) | | | | |
| hardener | 0.5 | 0.5 | 0.5 | 0.5 |
| (parts by weight) | | | | |
| methyl ethyl ketone | 9.62 | 12.5 | 12.5 | 6.34 |
| (parts by weight) | | | | |
| T value | 18.28 | 18.97 | 19.6 | 18.91 |
| peeling strength | 92 | 279 | 189.5 | 35.06 |
| (gf/25 mm) | | | | |
| viscosity | 0.057 | 0.29 | 1 | 0.3 |
| (Pa · s) | | | | |
| self-assembly | pass | fail | fail | fail |
| test | | | | |
| test for | pass | pass | pass | fail |
| transferring chips | | | | |

As shown in Table 8, since the viscosity (at 140° C.) of the film prepared from the conductive composition of Example 5 is less than 0.1 Pa·s, the conductive powder can freely move within the film. As a result, the film of Example 5 can pass the test for transferring chips. Furthermore, when the T value is greater than 18.9 resulting from increasing the amount of epoxy resin, the viscosity (at 140° C.) of the films prepared from the conductive compositions of Comparative Examples 6-8 is greater than 0.29 Pa·s. As a result, the films of Comparative Examples 6-8 cannot pass the test for transferring chips, due to the high viscosity.

Accordingly, the disclosure provides a conductive composition and the method for fabricating a micro light-emitting diode display device employing the same. The film prepared from the conductive composition of the disclosure is viscous at room temperature. As a result, the film prepared from the conductive composition of the disclosure can serve as an anisotropic conductive adhesive layer disposed on a display substrate in order to bond micro light-emitting diodes transferred from a carrier.

In addition, while the film prepared from the conductive composition of the disclosure is subjected to a first thermal treatment to form a conductive layer, the organic portion of the film has a viscosity less than or equal to 0.1 Pa·s.

As a result, the conductive powder (or molten conductive powder) can freely move within the film so that the conductive powder may be self-assembled to form the conductive film between the electrode of the micro light-emitting diode and the contact pad due to surface tension difference, thereby achieving self-alignment of the conductive film. In addition, the first thermal treatment can form an electrical connection between the micro light-emitting diode and the contact pad of the display substrate without curing the film. As a result, the micro light-emitting diode on the display substrate may be subjected to a detection process, thereby identifying whether a faulty micro light-emitting diode is present or not. The faulty micro light-emitting diode can be easily removed and then replaced with a known good micro light-emitting diode.

Although the disclosure has been described by way of example and in terms of the preferred embodiments, it should be understood that various modifications and similar arrangements (as would be apparent to those skilled in the art) can be made herein without departing from the spirit and scope of the disclosure as defined by the appended claims.

What is claimed is:

1. A conductive composition, comprising:
a monomer, wherein the monomer has a weight (W1) of 5 to 90 parts by weight, wherein the monomer has n reactive functional groups, and n is 1, 2, 3, or 4, wherein the monomer has a molecular weight Mw1 equal to or less than 350;
an epoxy resin, wherein the epoxy resin has a weight W2 of 10 to 95 parts by weight, wherein the epoxy resin has an epoxy equivalent weight (EEW) from 160 g/Eq to 3500 g/Eq, and in particular, the total weight (W1+W2) of the monomer and the epoxy resin is 100 parts by weight, wherein the weight W1, the number n, the molecular weight Mw1, the weight W2, and the epoxy equivalent weight (EEW) satisfy the following relationship:
16.90≤Ln[(EEW²)×(Mw1/n)×(W2/(W1+W2)]≤18.90; and
50 to 150 parts by weight of conductive powder.

2. The conductive composition as claimed in claim 1, wherein the reactive functional group of the monomer is oxiranyl group, cyclohexene oxide group, oxetanyl group, vinyloxy group, allyloxy group, acrylate group, or methacrylate group.

3. The conductive composition as claimed in claim 1, wherein the monomer is trimethylolethane-oxetane, trimethylolpropane oxetane, trimethylolbutane oxetane, trimethylolpentane oxetane, trimethylolhexane oxetane, trimethylolheptane oxetane, trimethyloloctane oxetane, or trimethylolnonane oxetane, ethylene glycol diglycidyl ether, propylene glycol diglycidyl ether, butanediol diglycidyl ether, neopentyl glycol diglycidyl ether, hexanediol diglycidyl ether, cyclohexanedimethanol diglycidyl ether, bisphenol A diglycidyl ether (BADGE), bisphenol F diglycidyl ether (BFDGE), terephthalic acid diglycidyl ester, tetrahydrophthalic acid diglycidyl ester, hexahydrophthalic acid diglycidyl ester, triglycidyl p-aminophenol, triglycidyl isocyanurate, trimethylolpropane triglycidyl ether, or glycerol triglycidyl ether.

4. The conductive composition as claimed in claim 1, wherein the epoxy resin has a weight average molecular weight Mw2 of 500 to 7,000.

5. The conductive composition as claimed in claim 1, wherein a slope determined by linear regression of a plot of the logarithm of viscosity of the epoxy resin against the logarithm of temperature is between −8 and −20.

6. The conductive composition as claimed in claim 1, wherein the epoxy resin is bisphenol A epoxy resin, bisphenol F epoxy resin, bisphenol S epoxy resin, novolac epoxy resin, naphthyl group epoxy resin, anthracene-based epoxy resin, bisphenol A diglycidyl ether (BADGE) epoxy resin, ethylene glycol diglycidyl ether (EGDGE) epoxy resin, propylene glycol diglycidyl ether (PGDGE) epoxy resin, or 1,4-butanediol diglycidyl ether (BDDGE) epoxy resin.

7. The conductive composition as claimed in claim 1, wherein the conductive powder is tin-bismuth alloy, tin-indium alloy, tin-bismuth-indium alloy, tin-bismuth-antimony alloy, tin-silver-bismuth alloy, tin-copper-bismuth alloy, tin-silver-copper-bismuth alloy, tin-silver-indium alloy, tin-copper-indium alloy, tin-copper-silver-indium alloy, or tin-gold-copper-bismuth-indium alloy.

8. The conductive composition as claimed in claim 1, wherein the conductive powder has an average particle size of 1 μm to 100 μm.

9. The conductive composition as claimed in claim 1, further comprising 1 to 40 parts by weight of deoxidizer.

10. The conductive composition as claimed in claim 1, further comprising 0.01 to 10 parts by weight of hardener.

11. A conductive composition, comprising:
5 to 90 parts by weight of monomer;
10 to 95 parts by weight of epoxy resin, wherein the total weight of the monomer and the epoxy resin is 100 parts by weight; and
50 to 150 parts by weight of conductive powder,
wherein the logarithm of the viscosity (Pa·s) of the epoxy resin at T° C. is V1; the logarithm of the viscosity (Pa·s) of the epoxy resin at T+10° C. is V2; the logarithm of the viscosity (Pa·s) of the epoxy resin at T+20° C. is V3; and, the logarithm of the viscosity (Pa·s) of the epoxy resin at T+30° C. is V4; V1 is from 2.84 to 3.70; V>V2>V3>V4; and, [symbol] V1-V4≥1.83, and wherein V, V2, V3 and V4 satisfy one of the following relationships (1) or (2):
2.84≤V1<3,0<V4<1, and 1≤V2<2, or 1≤V3<2; or (1)
3≤V1<3.70,0.5≤V4<2, and 2≤V2<3, or 1≤V3<3. (2)

12. The conductive composition as claimed in claim 11, wherein the monomer has n reactive functional groups, and n is 1, 2, 3, or 4, and the molecular weight of the monomer is less than or equal to 350.

13. The conductive composition as claimed in claim 12, wherein the reactive functional group of the monomer is oxiranyl group, cyclohexene oxide group, oxetanyl group, vinyloxy group, allyloxy group, acrylate group, or methacrylate group.

14. The conductive composition as claimed in claim 11, wherein the monomer is trimethylolethane-oxetane, trimethylolpropane oxetane, trimethylolbutane oxetane, trimethylolpentane oxetane, trimethylolhexane oxetane, trimethylolheptane oxetane, trimethyloloctane oxetane, or trimethylolnonane oxetane, ethylene glycol diglycidyl ether, propylene glycol diglycidyl ether, butanediol diglycidyl ether, neopentyl glycol diglycidyl ether, hexanediol diglycidyl ether, cyclohexanedimethanol diglycidyl ether, bisphenol A diglycidyl ether (BADGE), bisphenol F diglycidyl ether (BFDGE), terephthalic acid diglycidyl ester, tetrahydrophthalic acid diglycidyl ester, hexahydrophthalic acid diglycidyl ester, triglycidyl p-aminophenol, triglycidyl isocyanurate, trimethylolpropane triglycidyl ether, or glycerol triglycidyl ether.

15. The conductive composition as claimed in claim 11, wherein the epoxy resin has an epoxy equivalent weight (EEW) from 160 g/Eq to 3500 g/Eq.

16. The conductive composition as claimed in claim 11, wherein a slope determined by linear regression of a plot of the logarithm of viscosity of the epoxy resin against the logarithm of temperature is between −8 and −20.

17. The conductive composition as claimed in claim 11, wherein the epoxy resin is bisphenol A epoxy resin, bisphenol F epoxy resin, bisphenol S epoxy resin, novolac epoxy resin, naphthyl group epoxy resin, anthracene-based epoxy resin, bisphenol A diglycidyl ether (BADGE) epoxy resin, ethylene glycol diglycidyl ether (EGDGE) epoxy resin, propylene glycol diglycidyl ether (PGDGE) epoxy resin, or 1,4-butanediol diglycidyl ether (BDDGE) epoxy resin.

18. The conductive composition as claimed in claim 11, wherein the conductive powder is tin-bismuth alloy, tin-indium alloy, tin-bismuth-indium alloy, tin-bismuth-antimony alloy, tin-silver-bismuth alloy, tin-copper-bismuth alloy, tin-silver-copper-bismuth alloy, tin-silver-indium alloy, tin-copper-indium alloy, tin-copper-silver-indium alloy, or tin-gold-copper-bismuth-indium alloy.

19. The conductive composition as claimed in claim 11, wherein the conductive powder has an average particle size of 1 μm to 100 μm.

20. The conductive composition as claimed in claim 11, further comprising:
1 to 40 parts by weight of deoxidizer.

21. The conductive composition as claimed in claim 11, further comprising 0.01 to 10 parts by weight of hardener.

22. A method for fabricating a micro light-emitting diode display device, comprising:
providing a display substrate, wherein the display substrate has a plurality of contact pads disposed on the top surface of the display substrate;
forming a film of the conductive composition as claimed in claim 1 on the top surface of the display substrate, wherein the film covers the contact pad;
providing a carrier, wherein a plurality of micro light-emitting diodes are disposed on the carrier, wherein each micro light-emitting diode has an electrode;
transferring the micro light-emitting diodes to the display substrate, wherein each micro light-emitting diode is bonded on the corresponding contact pad via the film;
subjecting the film to a first thermal treatment so that the conductive powder of the film forms a conductive layer, and the electrode of the micro light-emitting diode is electrically connected to the contact pad via the conductive layer; and
subjecting the film to a second thermal treatment.
